(19) United States
(12) Patent Application Publication
(10) Pub. No.: US 2023/0395747 A1
(43) Pub. Date: Dec. 7, 2023

(54) CURRENT SPREADING LAYER STRUCTURES FOR LIGHT-EMITTING DIODE CHIPS

(71) Applicant: CreeLED, Inc., Durham, NC (US)

(72) Inventors: Michael Check, Holly Springs, NC (US); Justin White, Morrisville, NC (US); Steven Wuester, Wake Forest, NC (US); Kevin Haberern, Cary, NC (US); Colin Blakely, Raleigh, NC (US); Jesse Reiherzer, Raleigh, NC (US)

(21) Appl. No.: 18/302,149

(22) Filed: Apr. 18, 2023

Related U.S. Application Data
(60) Provisional application No. 63/365,645, filed on Jun. 1, 2022.

(51) Int. Cl. H01L 33/14; H01L 33/10

(52) U.S. Cl. CPC H01L 33/14; H01L 33/10

(57) ABSTRACT

Solid-state lighting devices including light-emitting diodes (LEDs) and more particularly current spreading layer structures for LED chips are disclosed. LED chips include active LED structures with current spreading layer arrangements relative to reflective structures that provide efficient current injection into the active LED structures while also providing improved light extraction. Current spreading layers include openings that allow portions of dielectric reflector layers to form interfaces with active LED structures adjacent the current spreading layers. Metal reflector layers are provided on the dielectric reflector layers, and reflective layer interconnects are formed through the dielectric reflector layers to contact portions of the current spreading layer.

### RELATED APPLICATIONS

This application claims the benefit of provisional patent application Ser. No. 63/365,645, filed Jun. 1, 2022, the disclosure of which is hereby incorporated herein by reference in its entirety.

### FIELD OF THE DISCLOSURE

The present disclosure relates to solid-state lighting devices including light-emitting diodes (LEDs) and more particularly to current spreading layer structures for LED chips.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. If photons are internally reflected in a repeated manner, then such photons will eventually be absorbed and never provide visible light that exits an LED. To increase the opportunity for photons to exit an LED, it has been found useful to pattern, roughen, or otherwise texture the interface between an LED surface and the surrounding environment to provide a varying surface that increases the probability of refraction over internal reflection and thus enhances light extraction. Reflective surfaces may also be provided to reflect generated light so that such light may contribute to useful emission from an LED chip. LEDs have been developed with internal reflective surfaces or layers to reflect generated light.

The quantum efficiency of an LED can also be limited by other factors, such as how well current is able to spread within an LED. To increase current spreading for LEDs, and in particular for larger area LEDs, it has been found useful to add layers of high electrical conductivity over one or more epitaxial layers of an LED. Additionally, electrodes for the LEDs can have larger surface areas and may include various electrode extensions or fingers that are configured to route and more evenly distribute current across an LED.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs) and more particularly to current spreading layer structures for LED chips. LED chips include active LED structures with current spreading layer arrangements relative to reflective structures that provide efficient current injection into the active LED structures while also providing improved light extraction. Current spreading layers include openings that allow portions of dielectric reflector layers to form interfaces with active LED structures adjacent the current spreading layers. Metal reflector layers are provided on the dielectric reflector layers, and reflective layer interconnects are formed through the dielectric reflector layers to contact portions of the current spreading layer.

In one aspect, an LED chip, comprises: an active LED structure comprising an n-type layer, a p-type layer, and an active layer that is between the n-type layer and the p-type layer; a current spreading layer on the active LED structure; and a dielectric reflector layer on the current spreading layer, the current spreading layer forming a plurality of openings and portions of the dielectric reflector layer extend through the plurality of openings. In certain embodiments, the current spreading layer comprises indium tin oxide. In certain embodiments, the dielectric reflector layer comprises silicon dioxide. The LED chip may further comprise a metal reflector layer on the dielectric reflector layer and a plurality of reflective layer interconnects that extend from the metal reflector layer and through the dielectric reflector layer. In certain embodiments, the plurality of reflective layer interconnects contact portions of the current spreading layer. In certain embodiments, the plurality of openings of the current spreading layer define a plurality of discontinuous regions of the current spreading layer. In certain embodiments, the plurality of reflective layer interconnects contact the plurality of discontinuous regions of the current spreading layer. In certain embodiments, the plurality of openings of the current spreading layer define a plurality of regions of the current spreading layer that are connected by extensions of the current spreading layer.

In certain embodiments, the LED chip further comprises an n-contact interconnect arranged to extend through the current spreading layer, the p-type layer, and the active layer to contact a portion of the n-type layer, wherein edges of the current spreading layer are laterally spaced from the n-contact interconnect. In certain embodiments, the edges of the current spreading layer form a non-circular shape about a periphery of the n-contact interconnect.

In another aspect, an LED chip comprises: an active LED structure comprising an n-type layer, a p-type layer, and an active layer that is between the n-type layer and the p-type layer; a plurality of current spreading regions on the active LED structure, each current spreading region of the plurality of current spreading regions being discontinuous with other current spreading regions of the plurality of current spreading regions; a dielectric reflector layer on the plurality of current spreading regions; and a metal reflector layer on the dielectric reflector layer and electrically coupled to the plurality of current spreading regions by a plurality of reflective layer interconnects that extend from the metal reflector layer and through the dielectric reflector layer. In certain embodiments, each current spreading region of the plurality of current spreading regions is electrically coupled to the metal reflector layer by a single reflective layer interconnect of the plurality of reflective layer interconnects. In certain embodiments, the reflective layer interconnects comprise a same material as the metal reflector layer. In certain embodiments, portions of the dielectric reflector layer extend between adjacent current spreading regions of the plurality of current spreading regions. In certain embodiments, the portions of the dielectric reflector layer contact the active LED structure between the adjacent current spreading regions of the plurality of current spreading regions. In certain embodiments, each current spreading region of the plurality of current spreading regions forms a circular shape. In certain embodiments, a diameter of each circular shape is greater than a diameter of each reflective layer interconnect of the plurality of reflective layer interconnects. In certain embodiments, each current spreading region of the plurality of current spreading regions forms a shape of a square, a rectangle, an oval, a hexagon, or an octagon. In certain embodiments, diameters of individual reflective layer interconnects of the plurality of reflective layer interconnects vary across the active LED structure.

The LED chip may further comprise an n-contact interconnect arranged to extend through the plurality of current spreading regions, the p-type layer, and the active layer to electrically couple with the n-type layer, wherein: the plurality of reflective layer interconnects comprises a first reflective layer interconnect and a second reflective layer interconnect; the first reflective layer interconnect is positioned closer to the n-contact interconnect than the second reflective layer interconnect, and a diameter of the first reflective layer interconnect is larger than a diameter of the second reflective layer interconnect. The LED chip may further comprise an n-contact interconnect arranged to extend through the plurality of current spreading regions, the p-type layer, and the active layer to electrically couple with the n-type layer, wherein: the plurality of current spreading regions comprise a first current spreading region and a second current spreading region such that the first current spreading region is closer to the n-contact interconnect than the second current spreading region; and a diameter of the first current spreading region is larger than a diameter of the second current spreading region.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a general cross-section of a portion of a light-emitting diode (LED) chip that includes interconnects that provide electrically conductive paths through a dielectric layer to a current spreading layer according to principles of the present disclosure.

FIG. 2 is a cross-sectional view of a representative LED chip arranged in a flip-chip configuration according to principles of the present disclosure.

FIG. 3 is a view of an LED chip from the perspective of the current spreading layer relative to locations of the n-contact interconnects after the current spreading layer is formed.

FIG. 4 is a view of an LED chip that is similar to the LED chip of FIG. 3 illustrating discontinuous regions of the current spreading layer.

FIG. 5A is a view of the LED chip of FIG. 4 illustrating a pattern of various regions of the current spreading layer.

FIG. 5B is a view of an LED chip that is similar to the LED chip of FIG. 5A for embodiments where the current spreading layer forms regions that are more tightly packed.

FIG. 5C is a view of an LED chip that is similar to the LED chip of FIG. 5A for embodiments where certain regions of the current spreading layer are connected with one another.

FIG. 5D is a view of an LED chip that is similar to the LED chip of FIG. for embodiments where the current spreading layer forms a continuous structure and certain openings thereof define locations for the n-contact interconnects.

FIG. 6A is a view of an LED chip that is similar to the LED chip of FIG. 5A and illustrates a pattern of the n-contact interconnects and the regions of the current spreading layer according to principles of the present disclosure.

FIG. 6B is a view of the regions of the current spreading layer from FIG. 6A with an arrangement of the reflective layer interconnects.

FIG. 6C is a view of the regions of the current spreading layer from FIG. 6A with an alternative arrangement of the reflective layer interconnects.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to current spreading layer structures for LED chips. LED chips include active LED structures with current spreading layer arrangements relative to reflective structures that provide efficient current injection into the active LED structures while also providing improved light extraction. Current spreading layers include openings that allow portions of dielectric reflector layers to form interfaces with active LED structures adjacent the current spreading layers. Metal reflector layers are provided on the dielectric reflector layers, and reflective layer interconnects are formed through the dielectric reflector layers to contact portions of the current spreading layer.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light transmissive optical properties.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations. In certain embodiments, one or more surfaces of LED chips may be conformally coated with one or more lumiphoric materials, while other surfaces of such LED chips and/or associated submounts may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) are coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described may also be applicable to flip-chip structures where anode and cathode connections are made from a same side of the LED chip for flip-chip mounting to another surface.

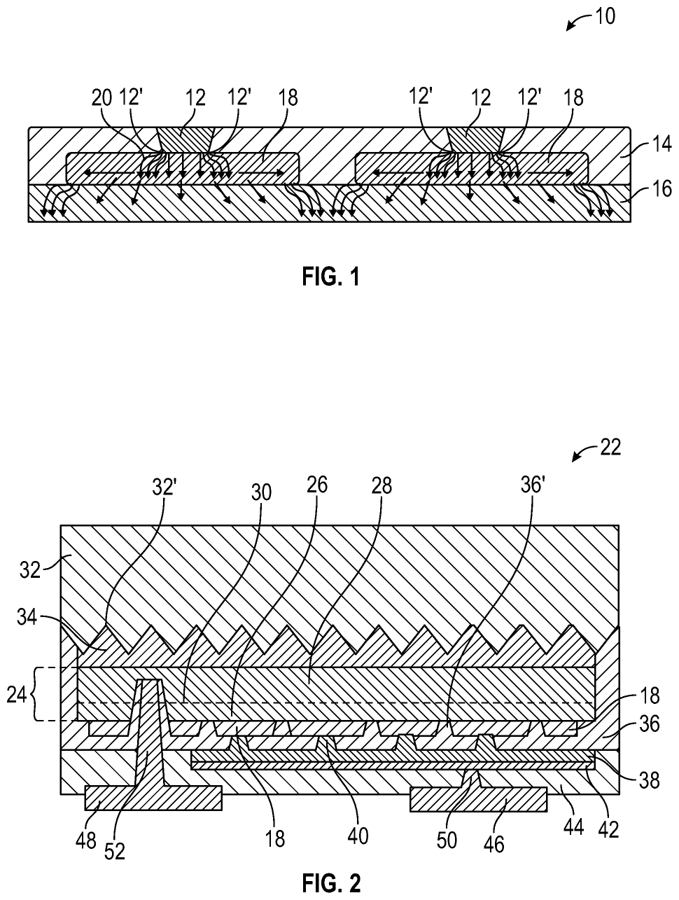

FIG. 1 is a general cross-section of a portion of an LED chip 10 that includes interconnects 12, or vias, that provide electrically conductive paths through a dielectric layer 14. For example, the interconnect 12 may be electrically coupled to a semiconductor layer 16 and/or an intervening current spreading layer 18. In the context of LED chip structures, the semiconductor layer 16 may embody an n-type layer or a p-type layer of an active LED structure, and the current spreading layer 18 may embody a layer of conductive material, for example a transparent conductive oxide such as indium tin oxide (ITO) or a metal such as platinum (Pt), although other materials may be used. In such an arrangement, a majority of current 20 is ejected along edges 12′ of the interconnect 12, with less amounts of the current 20 being ejected centrally with respect to the interconnect 12. The current spreading layer 18 also serves to laterally spread the current 20 before the current 20 is injected into the semiconductor layer 16, thereby providing increased current injection area. While providing such benefits, the current spreading layer 18 can sometimes impact device performance. For example, the current spreading layer 18 may absorb some percentage of light generated by the active LED structure. In this regard, the current spreading layer 18 may be formed in segments across the semiconductor layer 16 so that portions of the dielectric layer 14 are formed on the semiconductor layer 16 in between the segments of the current spreading layer 18. In certain embodiments, the material of the dielectric layer 14 may form an index of refraction step with the semiconductor layer 16 so that light reaching this interface may be redirected or otherwise reflected. As such, the dielectric layer 14 may serve as a dielectric reflector. By proving the current spreading layer 18 in segments with portions of the dielectric layer 14 therebetween, the LED chip 10 may exhibit sufficient current spreading while also having increased light extraction. Additionally, separating the current spreading layer 18 into segments allows fine tuning of current injection across the LED chip 10.

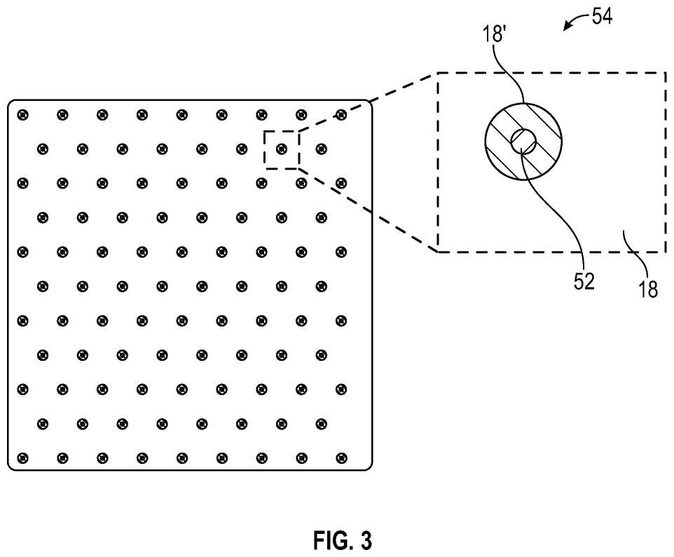

FIG. 2 is a cross-sectional view of a representative LED chip 22 arranged in a flip-chip configuration, although other configurations are possible. The LED chip 22 includes an active structure 24 comprising a p-type layer 26, an n-type layer 28, and an active layer 30 formed on a substrate 32. In certain embodiments, one or more buffer layers and/or undoped layers 34 may be provided between the substrate 32 and the active LED structure 24. The substrate 32 may embody a patterned substrate such that a surface 32′ of the substrate 32 closest to the active LED structure 24 is patterned. In certain embodiments, the n-type layer 28 is between the active layer 30 and the substrate 32. In other embodiments, the doping order may be reversed. The substrate 32 can comprise many different materials such as SiC or sapphire and can have one or more surfaces that are shaped, textured, or patterned to enhance light extraction. In certain embodiments, the substrate 32 is light transmissive (preferably transparent) and may include a patterned surface 32′ that is proximate the active LED structure 24 and includes multiple recessed and/or raised features.

In FIG. 2, a first reflective layer 36 is provided on portions of the p-type layer 26 with the current spreading layer 18 therebetween in a manner similar to FIG. 1. In this regard, the first reflective layer 36 may be provided in a similar arrangement as the dielectric layer 14 of FIG. 1. The first reflective layer 36 may comprise many different materials and preferably comprises a material that presents an index of refraction step with the material of the active LED structure 24 to promote total internal reflection (TIR) of light generated from the active LED structure 24. Light that experiences TIR is redirected without experiencing absorption or loss and can thereby contribute to useful or desired LED chip emission. In certain embodiments, the first reflective layer 36 comprises a material with an index of refraction lower than the index of refraction of the active LED structure 24 material. The first reflective layer 36 may comprise many different materials, with some having an index of refraction less than 2.3, while others can have an index of refraction less than 2.15, less than 2.0, and less than 1.5. In some embodiments the first reflective layer 36 comprises a dielectric material, with some embodiments comprising silicon dioxide (SiO₂) and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. In certain embodiments, the first reflective layer 36 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with an active LED structure 24 comprising GaN and the first reflective layer 36 that comprises SiO₂ can have a sufficient index of refraction step between the two to allow for efficient TIR of light. The first reflective layer 36 can have different thicknesses depending on the type of materials used, with some embodiments having a thickness of at least 0.2 microns (μm). In some of these embodiments, the first reflective layer 36 can have a thickness in the range of 0.2 μm to 0.7 μm, while in some of these embodiments the thickness can be approximately 0.5 μm. Portions of the first reflective layer 36 may extend along mesa sidewalls of the active LED structure 24.

As described above, the current spreading layer 18 in FIG. 2 is provided with a similar arrangement described above for FIG. 1. Accordingly, rather than continuously covering the p-type layer 26, the current spreading layer 18 is formed with a number of openings or even discontinuous regions that allow portions 36′ of the first reflective layer 36 to extend through the current spreading layer 18 and contact the p-type layer 26. In this manner, interfaces formed between the p-type layer 26 and the first reflective layer 36 that do not include the current spreading layer 18 may exhibit increased reflectivity to light generated by the active LED structure 24. Even though the current spreading layer 18 does not continuously cover the p-type layer 26, the openings or discontinuous regions of the current spreading layer 18 may have small enough lateral dimensions to still suitably spread current along the p-type layer 26.

The LED chip 22 may further include a second reflective layer 38 that is on the first reflective layer 36 such that the first reflective layer 36 is arranged between the active LED structure 24 and the second reflective layer 38. The second reflective layer 38 may include a metal layer that is configured to reflect any light from the active LED structure 24 that may pass through the first reflective layer 36. The second reflective layer 38 can comprise many different materials such as Ag, gold (Au), Al, or combinations thereof. As illustrated, the second reflective layer 38 may include one or more reflective layer interconnects 40 that provide electrically conductive paths through the first reflective layer 36 to the current spreading layer 18. In certain embodiments, the reflective layer interconnects 40 comprise reflective layer vias. Accordingly, the first reflective layer 36, the second reflective layer 38, and the reflective layer interconnects 40 form a reflective structure of the LED chip 22. In some embodiments, the reflective layer interconnects 40 comprise the same material as the second reflective layer 38 and are formed at the same time as the second reflective layer 38. In other embodiments, the reflective layer interconnects 40 may comprise a different material than the second reflective layer 38. The LED chip 22 may also comprise a barrier layer 42 on a side of the second reflective layer 38 opposite the first reflective layer 36 to prevent migration of the second reflective layer 38 material, such as Ag, to other layers. Preventing this migration helps the LED chip 22 maintain efficient operation through its lifetime. The barrier layer 42 may comprise an electrically conductive material, with suitable materials including but not limited to sputtered Ti/Pt followed by evaporated Au bulk material or sputtered Ti/Ni followed by an evaporated Ti/Au bulk material. A passivation layer 44 is included on the barrier layer 42 as well as any portions of the second reflective layer 38 that may be uncovered by the barrier layer 42. The passivation layer 44 may further be arranged on portions of the first reflective layer 36 that are uncovered by the second reflective layer 38. The passivation layer 44 protects and provides electrical insulation for the LED chip 22 and can comprise many different materials, such as a dielectric material. In certain embodiments, the passivation layer 44 is a single layer, and in other embodiments, the passivation layer 44 comprises a plurality of layers. A suitable material for the passivation layer 44 includes but is not limited to SiN, SiNx, and/or Si₃N₄. In certain embodiments, the first reflective layer 36 comprises SiO₂ and the passivation layer 44 comprises SiN, SiNx, or Si₃N₄. In other embodiments, the first reflective layer 36 and at least a portion of the passivation layer 44 may each comprise SiO₂.

In FIG. 2, the LED chip 22 comprises a p-contact 46 and an n-contact 48 that are arranged on the passivation layer 44 and are configured to provide electrical connections with the active LED structure 24. The p-contact 46, which may also be referred to as an anode contact, may comprise one or more p-contact interconnects 50 that extend through the passivation layer 44 to the barrier layer 42 or the second reflective layer 38 to provide an electrical path to the p-type layer 26. In certain embodiments, the one or more p-contact interconnects 50 comprise one or more p-contact vias. The n-contact 48, which may also be referred to as a cathode contact, may comprise one or more n-contact interconnects 52 that extend through the passivation layer 44, the barrier layer 42, the first and second reflective layers 36, 38, the p-type layer 26, and the active layer 30 to provide an electrical path to the n-type layer 28. In certain embodiments, the one or more n-contact interconnects 52 comprise one or more n-contact vias. In operation, a signal applied across the p-contact 46 and the n-contact 48 is conducted to the p-type layer 26 and the n-type layer 28, causing the LED chip 22 to emit light from the active layer 30. The p-contact 46 and the n-contact 48 can comprise many different materials such as Au, copper (Cu), nickel (Ni), In, Al, Ag, tin (Sn), Pt, or combinations thereof. In still other embodiments, the p-contact 46 and the n-contact 48 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. As described above, the LED chip 22 is arranged for flip-chip mounting and the p-contact 46 and n-contact 48 are configured to be mounted or bonded to a surface, such as a printed circuit board. While FIG. 2 is described in the context of a flip-chip structure, the principles disclosed for one or more of the current spreading layer 18, first reflective layer 36, second reflective layer 38, and barrier layer 42 are readily applicable to other chip structures.

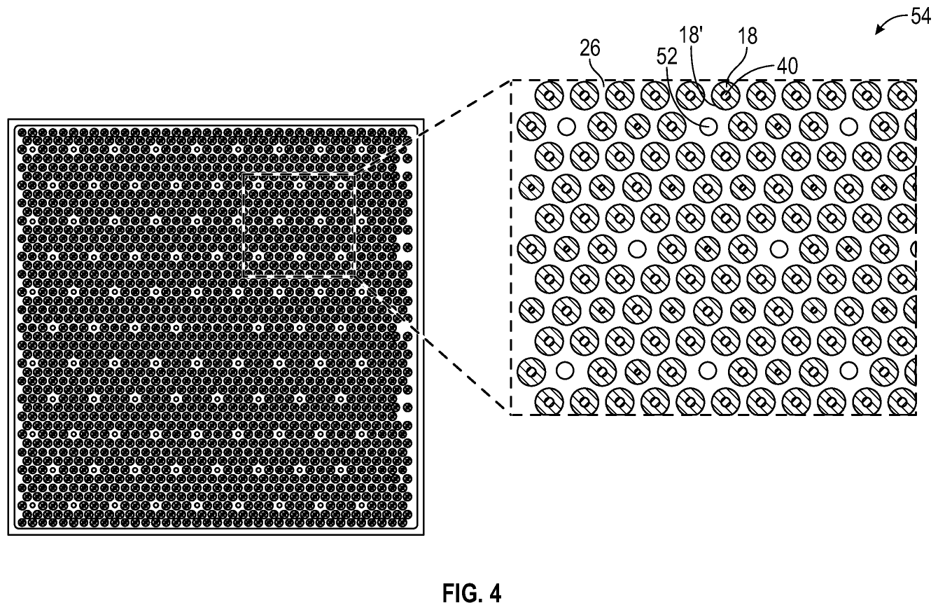

FIG. 3 is a view of an LED chip 54 from the perspective of the current spreading layer 18 relative to locations of the n-contact interconnects 52 after the current spreading layer 18 is formed. While the material of the n-contact interconnects 52 of FIG. 2 has not been formed yet in FIG. 3, for the purposes of this discussion, the openings or locations thereof are indicated in FIG. 3 and will be referred to hereinafter as the n-contact interconnects 52. In certain embodiments, the current spreading layer 18 forms an edge 18′ that is pulled back or inset from the n-contact interconnects 52. Some pull back is necessary to avoid electrical shorting if the current spreading layer 18 were to contact the n-contact interconnects 52. However, by increasing the distance between the edges 18′ of the current spreading layer 18 and the n-contact interconnects 52, more reflective material of the first reflective layer 36 may form increased interfaces with the portions of the active LED structure 24 of FIG. 2 that are adjacent the n-contact interconnects 52. Additionally, by increasing the distances of the edges 18′, reduced current injection at the adjacent portions of the active LED structure 24 may result in reduced non-radiative combination along sidewalls of the active LED structure 24 near the n-contact interconnects 52 due to Shockley-Read-Hall recombination.

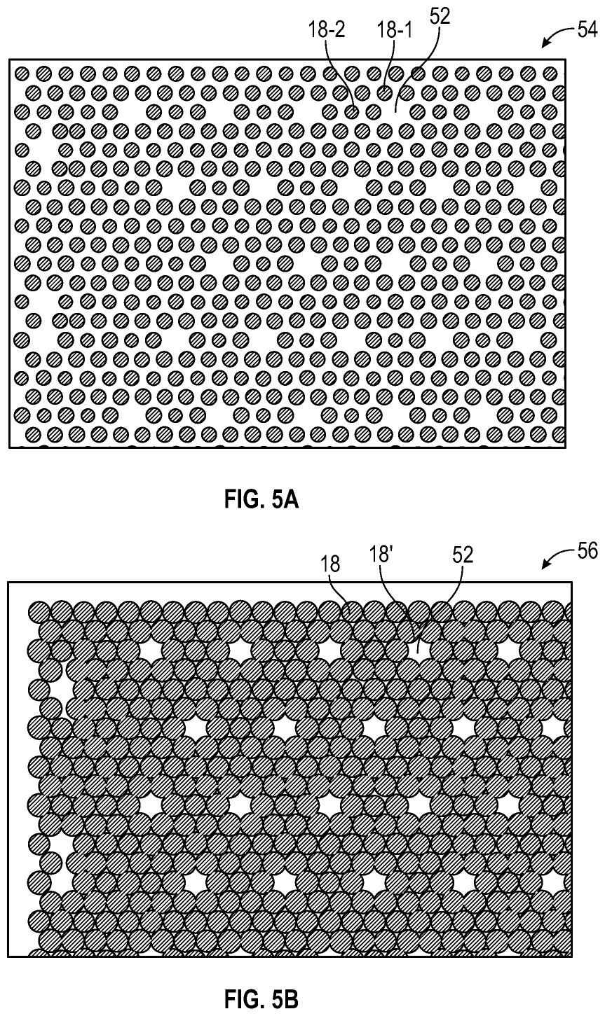

FIG. 4 is a view of an LED chip 56 that is similar to the LED chip 54 of FIG. 3 illustrating discontinuous regions of the current spreading layer 18. In a similar manner as FIG. 3, the material of the n-contact interconnects 52 of FIG. 2 has not been formed yet in FIG. 4, but the corresponding openings or locations thereof are indicated in FIG. 4 and will be referred to hereinafter as the n-contact interconnects 52. Additionally, while the material of the reflective layer interconnects 40 of FIG. 2 has also not been formed yet in FIG. 4, the corresponding openings or locations thereof are indicated in FIG. 4 and will be referred to hereinafter as the reflective layer interconnects 40. As illustrated, the current spreading layer 18 is formed as an array of discontinuous regions or islands across the p-type layer 26. In certain embodiments, the regions of the current spreading layer 18 are arranged with a close enough spacing that provides suitable current spreading across the entire surface area of the p-type layer 26 while also leaving enough portions of the p-type layer 26 uncovered by the current spreading layer 18. These uncovered regions of the p-type layer 26 in FIG. 4 correspond with areas where the first reflective layer 36 of FIG. 2 may contact the p-type layer 26 without the current spreading layer 18 therebetween to exhibit increased reflectivity.

As further illustrated in FIG. 4, diameters of the reflective layer interconnects 40 may be formed smaller than areas of the regions of the current spreading layer 18. In this regard, alignment tolerances may be improved while also providing increased coverage of the first reflective layer 36 along portions of the current spreading layer 18 adjacent the reflective layer interconnects 40. The structure of the current spreading layer 18 and the reflective layer interconnects 40 may provide the ability to fine tune current spreading across the p-type layer 26. For example, the reflective layer interconnects 40 may be provided with larger diameters in positions that are closest to the n-contact interconnects 52 and smaller diameters in positions farther away from the n-contact interconnects 52. In further embodiments, sizes of the regions of the current spreading layer 18 may also scale in a similar manner. In the example of FIG. 4, the regions of the current spreading layer 18 are provided as circular regions of decreasing diameter with distance away from the n-contact interconnects 52. In other embodiments, the regions of the current spreading layer 18 may embody other shapes, such as squares, ovals, rectangles, hexagons, octagons, etc.

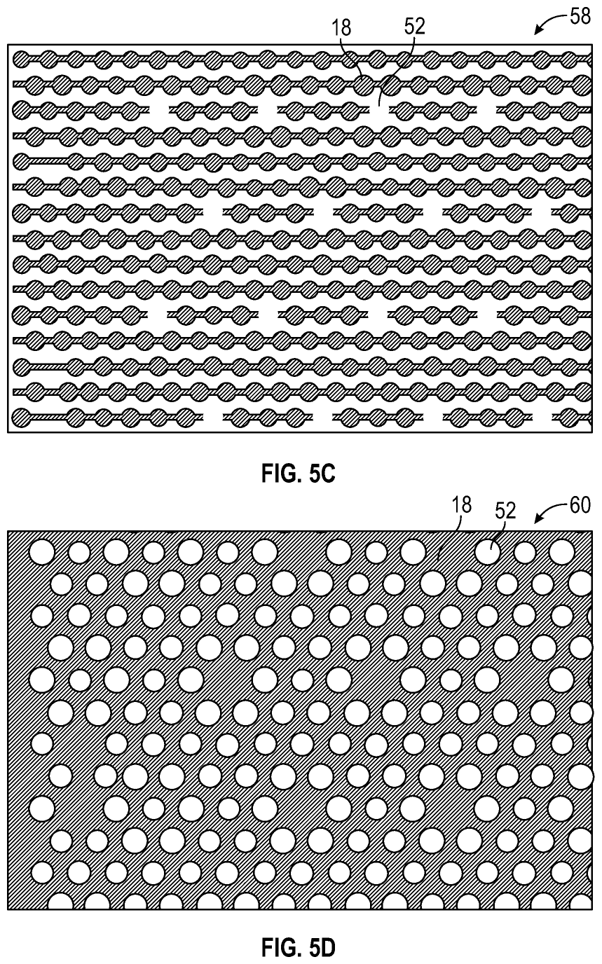

FIGS. 5A to 5D illustrate other arrangements of the current spreading layer 18 according to principles of the present disclosure. FIG. 5A is a view of the LED chip 54 of FIG. 4 illustrating a pattern of various regions 18-1, 18-2 of the current spreading layer 18. Locations of the n-contact interconnects 52 are shown as larger areas that are devoid of the current spreading layer regions 18-1, 18-2. As illustrated, the regions 18-1 that are closest to the n-contact interconnects 52 have larger diameters than the regions 18-2 that are spaced farther from the n-contact interconnects 52. In this manner, increased current spreading and injection may be provided along edges of the p-type layer 26 of FIG. 2 that are near the n-contact interconnects 52.

FIG. 5B is a view of an LED chip 56 that is similar to the LED chip 54 of FIG. 5A for embodiments where the current spreading layer 18 forms regions that are more tightly packed. In certain embodiments, the regions of the current spreading layer 18 may be tangent or even overlapping one another to provide increased current spreading. Additionally, edges 18′ of the current spreading layer 18 that bound locations for the n-contact interconnects 52 may be formed with non-circular shapes to maintain lateral spacing between the current spreading layer 18 and the n-contact interconnects 52 as described for FIG. 3.

FIG. 5C is a view of an LED chip 58 that is similar to the LED chip 54 of FIG. 5A for embodiments where certain regions of the current spreading layer 18 are connected with one another. For example, the current spreading layer 18 may form an array of regions with a shape, such as circular, and extensions of the current spreading layer 18 may connect adjacent ones of the regions together. In the example of FIG. 5C, rows are connected such that each row of regions of the current spreading layer 18 are part of a continuous portion of the current spreading layer 18. Such an arrangement may provide redundancy in the current spreading layer 18 in case one or more of the reflective layer interconnects 40 of FIG. 4 unintentionally misses its target region of the current spreading layer 18.

FIG. 5D is a view of an LED chip 60 that is similar to the LED chip 54 of FIG. 5A for embodiments where the current spreading layer 18 forms a continuous structure and certain openings thereof define locations for the n-contact interconnects 52 and other openings thereof define locations where the first reflective layer 36 may contact the p-type layer 26 as illustrated in FIG. 2.

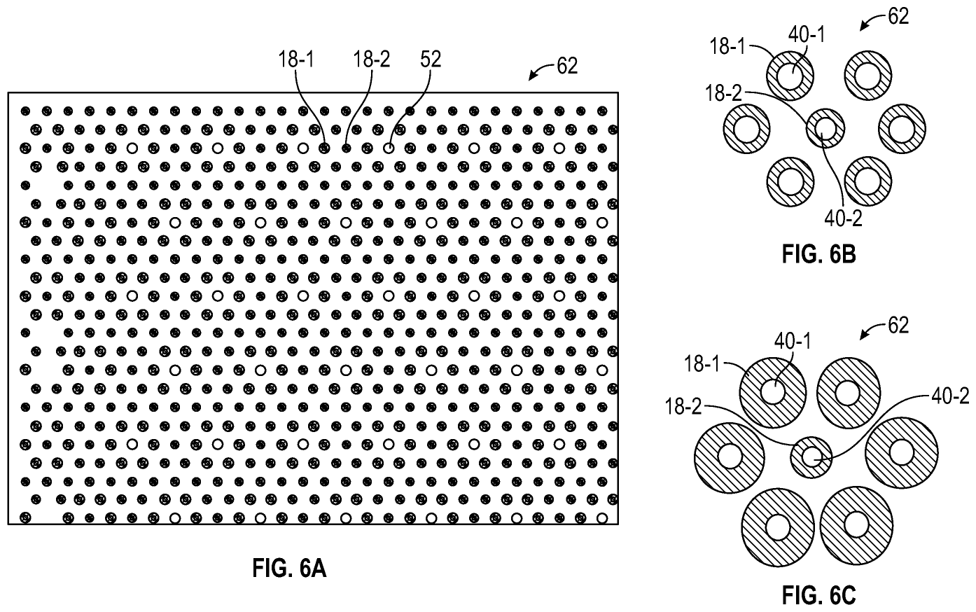

FIG. 6A is a view of an LED chip 62 that is similar to the LED chip 54 of FIG. 5A and illustrates a pattern of the n-contact interconnects 52 and the regions 18-1, 18-2 of the current spreading layer 18 according to principles of the present disclosure. FIG. 6B is a view of the regions 18-1, 18-2 of the current spreading layer 18 from FIG. 6A with an arrangement of reflective layer interconnects 40-1, 40-2. In FIG. 6B, the relative size of the reflective layer interconnects 40-1, 40-2 is coupled to or scales according to the size or area of the corresponding region 18-1, 18-2 of the current spreading layer 18. For example, the reflective layer interconnect 40-1 and the corresponding region 18-1 of the current spreading layer 18 are both proportionally larger than the reflective layer interconnect 40-2 and the corresponding region 18-2. FIG. 6C is a view of the regions 18-1, 18-2 of the current spreading layer 18 from FIG. 6A with alternative arrangement of the reflective layer interconnects 40-1, 40-2. In FIG. 6C, the relative size of the reflective layer interconnects 40-1, 40-2 is decoupled from the size of the corresponding region 18-1, 18-2 of the current spreading layer 18. For example, in FIG. 6C, each of the reflective layer interconnects 40-1, 40-2 may have a same size, regardless of an area of the corresponding region 18-1, 18-2.

In this regard, the embodiments of FIGS. 6A to 6C illustrate certain relationships between the reflective layer interconnects 40-1, 40-2 and the corresponding regions 18-1, 18-2 of the current spreading layer 18. The relative sizes may scale together or be independent of one another. In other embodiments, the sizes of the reflective layer interconnects 40-1, 40-2 and the corresponding regions 18-1, 18-2 of the current spreading layer 18 may change in opposite directions from one another. In still further embodiments, one of the reflective layer interconnects 40-1, 40-2 or the corresponding regions 18-1, 18-2 may have constant sizes while the other has variable sizing. In any of the above-described embodiments, certain regions 18-1, 18-2 of the current spreading layer 18 may be connected as illustrated in FIG. 5C. In still further embodiments, these structures could be further patterned into photonic crystal cavities to increase the total amount of light out of the LEDs.

As described herein, embodiments of the present disclosure provide chip architectures in LEDs that promote current injection with improved efficiency. Current spreading layer arrangements according to the principles allow for control of perimeter contact areas for current spreading layers and associated current spreading, injection, and light extraction.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer that is between the n-type layer and the p-type layer;
a current spreading layer on the active LED structure; and
a dielectric reflector layer on the current spreading layer, the current spreading layer forming a plurality of openings and portions of the dielectric reflector layer extend through the plurality of openings.

2. The LED chip of claim 1, wherein the current spreading layer comprises indium tin oxide and the dielectric reflector layer comprises silicon dioxide.

3. The LED chip of claim 1, further comprising a metal reflector layer on the dielectric reflector layer and a plurality of reflective layer interconnects that extend from the metal reflector layer and through the dielectric reflector layer.

4. The LED chip of claim 3, wherein the plurality of reflective layer interconnects contact portions of the current spreading layer.

5. The LED chip of claim 4, wherein the plurality of openings of the current spreading layer define a plurality of discontinuous regions of the current spreading layer.

6. The LED chip of claim 5, wherein the plurality of reflective layer interconnects contact the plurality of discontinuous regions of the current spreading layer.

7. The LED chip of claim 4, wherein the plurality of openings of the current spreading layer define a plurality of regions of the current spreading layer that are connected by extensions of the current spreading layer.

8. The LED chip of claim 1, further comprising an n-contact interconnect arranged to extend through the current spreading layer, the p-type layer, and the active layer to contact a portion of the n-type layer, wherein edges of the current spreading layer are laterally spaced from the n-contact interconnect.

9. The LED chip of claim 8, wherein the edges of the current spreading layer form a non-circular shape about a periphery of the n-contact interconnect.

10. A light-emitting diode (LED) chip, comprising:
an active LED structure comprising an n-type layer, a p-type layer, and an active layer that is between the n-type layer and the p-type layer;
a plurality of current spreading regions on the active LED structure, each current spreading region of the plurality of current spreading regions being discontinuous with other current spreading regions of the plurality of current spreading regions;
a dielectric reflector layer on the plurality of current spreading regions; and
a metal reflector layer on the dielectric reflector layer and electrically coupled to the plurality of current spreading regions by a plurality of reflective layer interconnects that extend from the metal reflector layer and through the dielectric reflector layer.

11. The LED chip of 10, wherein each current spreading region of the plurality of current spreading regions is electrically coupled to the metal reflector layer by a single reflective layer interconnect of the plurality of reflective layer interconnects.

12. The LED chip of claim 11, wherein the reflective layer interconnects comprise a same material as the metal reflector layer.

13. The LED chip of claim 12, wherein portions of the dielectric reflector layer extend between adjacent current spreading regions of the plurality of current spreading regions.

14. The LED chip of claim 13, wherein the portions of the dielectric reflector layer contact the active LED structure between the adjacent current spreading regions of the plurality of current spreading regions.

15. The LED chip of claim 10, wherein each current spreading region of the plurality of current spreading regions forms a circular shape.

16. The LED chip of claim 15, wherein a diameter of each circular shape is greater than a diameter of each reflective layer interconnect of the plurality of reflective layer interconnects.

17. The LED chip of claim 10, wherein each current spreading region of the plurality of current spreading regions forms a shape of a square, a rectangle, an oval, a hexagon, or an octagon.

18. The LED chip of claim 10, wherein diameters of individual reflective layer interconnects of the plurality of reflective layer interconnects vary across the active LED structure.

19. The LED chip of claim 10, further comprising an n-contact interconnect arranged to extend through the plurality of current spreading regions, the p-type layer, and the active layer to electrically couple with the n-type layer, wherein:
the plurality of reflective layer interconnects comprises a first reflective layer interconnect and a second reflective layer interconnect;
the first reflective layer interconnect is positioned closer to the n-contact interconnect than the second reflective layer interconnect, and
a diameter of the first reflective layer interconnect is larger than a diameter of the second reflective layer interconnect.

20. The LED chip of claim 10, further comprising an n-contact interconnect arranged to extend through the plurality of current spreading regions, the p-type layer, and the active layer to electrically couple with the n-type layer, wherein:
the plurality of current spreading regions comprise a first current spreading region and a second current spreading region such that the first current spreading region is closer to the n-contact interconnect than the second current spreading region; and
a diameter of the first current spreading region is larger than a diameter of the second current spreading region.
